(19) United States
(12) Patent Application Publication
(10) Pub. No.: US 2010/0155917 A1
(43) Pub. Date: Jun. 24, 2010

(54) SEMICONDUCTOR DEVICE AND METHOD FOR FABRICATING THE SAME

(76) Inventor: Tetsumasa MARUO, Osaka (JP)

Correspondence Address: MCDERMOTT WILL & EMERY LLP, 600 13TH STREET, NW, WASHINGTON, DC, 20005-3096, US

(21) Appl. No.: 12/612,193

(22) Filed: Nov. 4, 2009

(30) Foreign Application Priority Data
Dec. 18, 2008 (JP) 2008-322272
Sep. 1, 2009 (JP) 2009-201421

(51) Int. Cl. H01L 23/02; H01L 21/00

(52) U.S. Cl. 257/680; 438/113; 257/E23.18; 257/E21.001

(57) ABSTRACT

A semiconductor device includes: a semiconductor element having a light receiving region or a light emitting region on which a transparent member is attached, and a plurality of electrode pads; a substrate on which the semiconductor element is provided; and a resin covering the semiconductor element and side surfaces of the transparent member. The first area corresponding to part of an upper surface of the semiconductor element, which part is covered with the resin is smaller than the second area corresponding to parts of a lower surface of the semiconductor element and a lower surface of the substrate, which parts are covered with the resin.

### CROSS-REFERENCE TO RELATED APPLICATIONS

This application claims priority to Japanese Patent Application No. 2008-322272 filed on Dec. 18, 2008 and Japanese Patent Application No. 2009-201421 filed on Sep. 1, 2009, the disclosure of each of which including the specification, the drawings, and the claims is hereby incorporated by reference in its entirety.

### BACKGROUND

The present disclosure relates to semiconductor devices including light receiving elements or light emitting elements and to methods for fabricating the same.

In recent years, there is an increasing demand for high-density mounting of semiconductor devices as electronic equipment becomes smaller, thinner, and lighter. In addition, the packing density of semiconductor elements is desired to be increased by the advance of micromachining technology. To meet the demands, the so-called chip mounting technique of directly mounting semiconductor elements as chip size packages or bare chips has been proposed. There is a similar trend in semiconductor devices including light receiving elements or light emitting elements, and various arrangements thereof have been proposed.

For example, element structures and methods for fabricating the same have been proposed in order to obtain a thin, low-cost semiconductor device, in which a transparent member is directly attached by a transparent adhesive to a microlens in a light receiving region or a light emitting region of a semiconductor element. Examples of the semiconductor elements include light receiving elements and light emitting elements.

In this method, the microlens is directly formed on the semiconductor element having the light receiving region or the light emitting region. Further, on the microlens, the transparent member is directly attached parallel to the light receiving region or the light emitting region. Here, between the microlens and the transparent member, the transparent adhesive is completely filled without leaving space. Therefore, even if an environmental condition in which the semiconductor device including the light receiving element or the light emitting element is used is changed, the electric properties and the optical properties of the semiconductor device are ensured, and its reliability is ensured. Alternatively, when a semiconductor element having a light receiving region or a light emitting region is packaged in a conventionally used ceramic package, a certain volume of airspace which is not filled with a resin or the like may present between a microlens and a transparent member constituting the package. This may increase the thickness of the semiconductor device. However, also in this case, a semiconductor device has been proposed in which a rib supporting the transparent member is formed of a liquid resin to minimize airspace which is not filled with a resin or the like. Therefore, the semiconductor device can be mounted on a circuit module or the like, where the thickness of the semiconductor device is defined as a distance from a bottom surface to the transparent member. That is, it is possible to obtain a thin semiconductor device capable of being mounted directly, that is, at low cost, on the circuit module or the like.

A method for fabricating the semiconductor device described above is as follows. First, a plurality of semiconductor elements are bonded on a surface of a base material with a light receiving region or a light emitting region of each semiconductor element facing upward. Examples of the semiconductor elements include a light receiving element and a light emitting element. The semiconductor elements are aligned at predetermined intervals. Subsequently, the light receiving regions or the light emitting regions of the semiconductor elements are covered with protective films which are formed individually and are flexible. While each semiconductor element covered with the protective film is, together with the base material, clamped by a die having flat clamp surfaces, a sealing resin is filled into the space surrounded by the clamp surfaces of the die and by the protective films and the semiconductor elements adjacent thereto, thereby the resin is molded. After that, from the light receiving region or the light emitting region of each semiconductor element, the protective film is removed. Then, along the space between the semiconductor elements adjacent to each other at the predetermined intervals, the portions filled with the sealing resin are cut to form individual semiconductor devices.

FIGS. 6A and 6B are a cross-sectional view and a plan view of a back surface (e.g., a die pad surface) of a semiconductor device of a conventional example. It should be noted that FIG. 6A is a cross-sectional view along the line VI-VI of FIG. 6B. As shown in FIGS. 6A and 6B, a semiconductor element 102 is die bonded to a substrate 103. On a light receiving region or a light emitting region of the semiconductor element 102, a transparent member 101 is attached with a transparent adhesive 112 interposed therebetween. The semiconductor element 102 has a plurality of bonding pads 107. The bonding pads 107 are electrically connected to respective ones of a plurality of connection terminals 106 assigned to the substrate 103 via corresponding ones of Au wires 105. The semiconductor element 102, the Au wires 105, and side surfaces of the transparent member 101 are covered with a resin 104. It should be noted that an upper surface of the transparent member 101 and a lower surface of the substrate 103 (including the connection terminals 106) are exposed from the resin 104.

### SUMMARY

The semiconductor device of the conventional example shown in FIGS. 6A and 6B is a semiconductor device including a light receiving element or a light emitting element. Therefore, a principal plane (e.g., an upper surface) of the transparent member 101 is required to be exposed from the resin 104, while the side surfaces of the transparent member 101 are required to be covered with the resin 104.

However, in the semiconductor device of the conventional example, the size of the substrate 103 to which the semiconductor element 102 is die bonded is larger than the size of the semiconductor element 102 serving as a chip (i.e., the chip size). Therefore, the following problem may arise. That is, when the resin 104 covers around the transparent member 101, the volume of the resin 104 is relatively large at its portion close to the transparent member 101, while the volume of the resin 104 is relatively small at its portion close to the substrate 103 opposite to the transparent member 101, that is, at a die pad side. As a result, in the portion close to the transparent member 101 in which the volume the resin 104 is relatively large, the contraction stress of the resin 104 arises, which may cause a concave warp of the semiconductor device, that is, a downsized package of the conventional example.

Thus, when the semiconductor device including the light receiving element or the light emitting element concavely warps, the principal plane of the transparent member also warps concavely. Therefore, when it is attempted to directly attach the transparent member to a lens module such as a prism provided on the semiconductor element, adhering the entire surface of the transparent member on the lens module is difficult. As a result, an inclination may be caused at an adhesive section between the transparent member and the lens module, thereby shifting their optical axes, and the lens module such as a prism may be damaged. This may cause the problem that the assembly operation takes a long time and the quality is lowered.

In view of the above discussed problems, the present disclosure provides a low-cost semiconductor device having a high level of quality in which a concave warp of a transparent member in the semiconductor device including a light receiving element or a light emitting element is prevented to prevent the problems in optical properties.

For this purpose, a first semiconductor device of the present disclosure includes: a semiconductor element having a light receiving region or a light emitting region on which a transparent member is attached and a plurality of electrode pads; a substrate on which the semiconductor element is provided; and a resin covering the semiconductor element and side surfaces of the transparent member, wherein an area of a lower surface of the substrate is smaller than an area of an upper surface of the transparent member.

In the first semiconductor device of the present disclosure, the area of the lower surface of the substrate on which the semiconductor element is provided is smaller than the area of the upper surface of the transparent member. Thus, the resin can be sufficiently filled into the space under a lower surface of the semiconductor element opposite to the transparent member. This can suppress the formation of contraction stress of the resin at its portion close to the transparent member. Therefore, it is possible to reduce a concave warp of the transparent member caused by the contraction stress. In this way, it is possible to obtain a low-cost, highly reliable semiconductor device with the problems in optical properties being prevented.

Alternatively, for the aforementioned purpose, a second semiconductor device of the present disclosure includes: a semiconductor element having a light receiving region or a light emitting region on which a transparent member is attached and a plurality of electrode pads; a substrate on which the semiconductor element is provided; and a resin covering the semiconductor element and side surfaces of the transparent member, wherein a first area corresponding to part of an upper surface of the semiconductor element, which part is covered with the resin is smaller than a second area corresponding to parts of a lower surface of the semiconductor element and a lower surface of the substrate, which parts are covered with the resin.

In the second semiconductor device of the present disclosure, the area corresponding to the part of the upper surface (that is, a formation surface for the light receiving region or the light emitting region) of the semiconductor element, which part is covered with the resin (i.e., the first area) is smaller than the area corresponding to the parts of the lower surface of the semiconductor element and the lower surface of the substrate, which parts are covered with the resin (i.e., second area). In other words, the resin is sufficiently filled into the space under the lower surface of the semiconductor element opposite to the transparent member. This can suppress the formation of contraction stress of the resin at its portion close to the transparent member. Thus, it is possible to reduce the concave warp of the transparent member caused by the contraction stress. Moreover, the resin is also filled into the space under the lower surface of the substrate on which the semiconductor element is provided. This can further suppress the formation of the contraction stress of the resin at its portion close to the transparent member. Thus, it is possible to further reduce the concave warp of the transparent member. Therefore, it is possible to provide a low-cost, highly reliable semiconductor device with the problems in optical properties being prevented.

In the second semiconductor device of present disclosure, a thickness of part of the substrate in which the lower surface of the substrate is covered with the resin may be smaller than a thickness of the other part of the substrate.

In the second semiconductor device of the present disclosure, the advantage mentioned above can be ensured when the second area (the area corresponding to the parts of the lower surface of the semiconductor element and the lower surface of the substrate, which parts are covered with the resin) is 1.5 or more times as large as the first area (the area corresponding to the part of the upper surface of the semiconductor element, which part is covered with the resin).

In the first or second semiconductor device of the present disclosure, at least part of the lower surface of the substrate may be exposed from the resin.

In the first or second semiconductor device of the present disclosure, lower surfaces of a plurality of parts of the substrate which are spaced apart from each other may be exposed form the resin. In other words, the space under the lower surface of the semiconductor element except the exposed surfaces of the substrate may be filled with the resin. In this way, the resin is sufficiently filled into the space under the lower surface of the semiconductor element. This can further suppress the formation of the contraction stress of the resin at its portion close to the transparent member. Thus, it is possible to further reduce the concave warp of the transparent member.

The first or second semiconductor device of the present disclosure may further include: a plurality of connection terminals assigned to the substrate; and bonding wires electrically connecting the plurality of electrode pads to corresponding ones of the plurality of connection terminals. Here, the bonding wires may be made of gold.

In the first or second semiconductor device of the present disclosure, the semiconductor element may be flip-chip bonded to the substrate.

In the first or second semiconductor device of the present disclosure, the transparent member may be attached on the light receiving region or the light emitting region of the semiconductor element with a transparent adhesive interposed therebetween.

It should be noted that when the first or second semiconductor device of the present disclosure is used, for example, as a camera module, it is possible to obtain a small, thin, highly reliable camera module with the concave warp of the transparent member being reduced.

Alternatively, when the first or second semiconductor device of the present disclosure is used, for example, as a medical endoscope module, it is possible to obtain a small, thin, highly reliable medical endoscope module with the concave warp of the transparent member being reduced.

A method for fabricating the first or second semiconductor device of the present disclosure includes: preparing the substrate on which multiple ones of the semiconductor element are arranged in a matrix pattern; molding the resin while the substrate is clamped, with release sheets being provided respectively between a die surface and upper surfaces of the transparent members and between a die surface and the lower surface of the substrate; and after the molding, cutting the substrate to separate the semiconductor elements from one another.

According to the method for fabricating the semiconductor device of the present disclosure, after resin sealing, the substrate is cut to separate the semiconductor element from one another, thereby a plurality of semiconductor devices can be formed in one process. Moreover, the resin sealing is carried out while the substrate is clamped, with the release sheets being provided respectively between the die surface and the upper surface of the transparent member and between the die surface and the lower surface of the substrate. Thus, the resin does not come into contact with the upper surface of the transparent member and the lower surface of the substrate which are respectively covered with the release sheets. Therefore, it is possible to obtain a semiconductor device in which the resin does not cover the upper surface of the transparent member and the lower surface of the substrate.

In the method for fabricating the semiconductor device of the present disclosure, in the molding, a heat-resistant sheet instead of the release sheet may be provided between the die surface and the lower surface of the substrate. In this way, the release sheet for the lower surface (exposed surface) of the substrate on which the semiconductor element is provided can be dispensed with. Thus, clamping using the dies for resin sealing can be performed more stably. Therefore, it is possible to further increase yield of the semiconductor device.

As described so far, according to the present disclosure, it is possible to reduce the concave warp of the semiconductor device including the light receiving element or the light emitting element, in particular, the concave warp of the transparent member. Therefore, in the case where the transparent member is directly attached to a lens module such as a prism, the entire surface of the transparent member can be adhered easily to the lens module. This can prevent an inclination from being caused at an adhesive section between the transparent member and the lens module, thereby preventing their optical axes from being shifted and the lens module such as a prism from being damaged. As a result, the time required for the assembly operation can be shortened, and the quality can be prevented from being lowered.

That is, since the present disclosure relates to semiconductor devices including light receiving elements or light emitting elements and to a method for fabricating the same, and can achieve low-cost, highly reliable semiconductor devices with concave warps of transparent members being reduced, the present disclosure is suitable for, for example, image sensors such as mobile telephones and digital cameras.

### BRIEF DESCRIPTION OF THE DRAWINGS

FIGS. 1A and 1B are a cross-sectional view and a plan view of a back surface of a semiconductor device according to Embodiment 1 of the present disclosure.

FIGS. 2A and 2B are a cross-sectional view and a plan view of a back surface of a semiconductor device according to Embodiment 2 of the present disclosure.

FIGS. 3A and 3B are a cross-sectional view and a plan view of a back surface of a semiconductor device according to Embodiment 3 of the present disclosure.

FIGS. 4A through 4E are cross-sectional views illustrating processes in a method for fabricating a semiconductor device according to Embodiment 4 of the present disclosure.

FIGS. 5A through 5C are cross-sectional views illustrating processes in the method for fabricating the semiconductor device according to Embodiment 4 of the present disclosure.

FIGS. 6A and 6B are a cross-sectional view and a plan view of a back surface of a semiconductor device according to a conventional example.

### DETAILED DESCRIPTION

Embodiments will be described below with reference to the drawings. It should be noted that in the drawings referenced, the thickness, length, etc. of components are not drawn to scale for the sake of clarity and illustration. Moreover, the number of the components such as electrodes, terminals, etc. is different from the number of the components actually provided, and for the sake of illustration, some of the components actually provided are shown as examples. Furthermore, materials, etc. of the components are not limited to the specific examples described below.

(Embodiment 1)

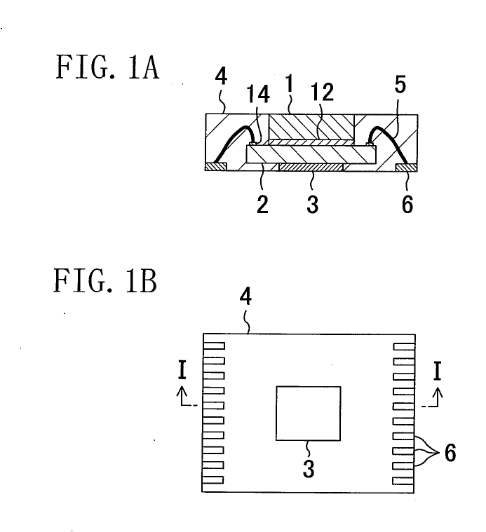

FIGS. 1A and 1B are a cross-sectional view and a plan view of a back surface (e.g., a die pad surface) of a semiconductor device according to Embodiment 1 of the present disclosure. It should be noted that FIG. 1A is a cross-sectional view along the line I-I of FIG. 1B. As shown in FIGS. 1A and 1B, a semiconductor element 2 is die bonded to a substrate 3. On a light receiving region or a light emitting region of the semiconductor element 2 (on each of the light receiving region and the light emitting region when the semiconductor element has both of the regions), a transparent member 1 is attached with a transparent adhesive 12 interposed therebetween. The semiconductor element 2 has a plurality of bonding pads 14. The bonding pads 14 are electrically connected to respective ones of a plurality of connection terminals 6 assigned to the substrate 3 via respective ones of Au wires 5. The semiconductor element 2, the Au wires 5, and side surfaces of the transparent member 1 are covered with a resin 4. It should be noted that an upper surface of the transparent member 1 and a lower surface of the substrate 3 (including the connection terminals 6) are exposed from the resin 4.

The present embodiment is configured particularly such that the area of the lower surface of the substrate 3 is smaller than the area of the upper surface of the transparent member 1. It should be noted that in the present embodiment, the lower surface of the substrate 3 to which the semiconductor element 2 is die bonded may be covered with the resin 4.

In the present embodiment, the area of the lower surface of the substrate 3 to which the semiconductor element 2 is die bonded is smaller than the area of the upper surface of the transparent member 1. Therefore, the resin 4 can be sufficiently filled also into the space under a lower surface of the semiconductor element 2 opposite to the transparent member 1. This can suppress the formation of contraction stress of the resin 4 at its portion close to the transparent member 1. Thus, it is possible to reduce a concave warp of the semiconductor device, particularly a concave warp of the transparent member 1 caused by the contraction stress. Therefore, in the case where the transparent member 1 is directly attached to a lens module such as a prism, the entire surface of the transparent member 1 can be adhered easily to the lens module. This can prevent an inclination from being caused at an adhesive section between the transparent member 1 and the lens module, thereby preventing their optical axes from being shifted, and can prevent the lens module such as a prism from being damaged. As a result, the time required for the assembly operation can be shortened, and the quality can be prevented from being lowered. Consequently, it is possible to provide a low-cost, highly reliable semiconductor device with the problems in optical properties being prevented.

It should be noted that in the present embodiment, for example, in a center section of the upper surface (e.g., the principal plane) of the semiconductor element 2, a light receiving region or a light emitting region in which a plurality of pixels are arranged in a matrix pattern may be set, and a microlens may be formed on each pixel. Moreover, for example, in a peripheral section of the upper surface (e.g., the principal plane) of the semiconductor element 2, a circuit region may be set, and a plurality of bonding pads 14 may be formed on the circuit region.

In the present embodiment, the plurality of bonding pads 14 of the semiconductor element 2 is electrically connected to the respective ones of the plurality of connection terminals 6 assigned to the substrate 3 via the respective ones of the Au wires 5. However, bonding wires made of another material may be used instead of the Au wires 5. Moreover, the semiconductor element 2 may be connected to the substrate 3 by flip-chip bonding instead of wire bonding.

In the present embodiment, a material as a base material of the semiconductor element 2 may be, for example, a silicon. However, in the case of application to a semiconductor laser or a light emitting diode, a group III-V compound, a group II-V compound, or the like may be used.

Moreover, in the present embodiment, the transparent member 1 has a size capable of covering the entire surface of the light receiving region or the light emitting region of the semiconductor element 2. Moreover, the upper surface and a lower surface of the transparent member 1 are processed into optically flat surfaces parallel to each other, and the side surfaces of the transparent member 1 are flat surfaces perpendicular to the upper and lower surfaces. Here, a projection plane (a plane shape viewed from above) of the transparent member 1 may be of rectangular shape, and four corners of the rectangle may be cut at an angle of about 45°. Further, edges of at least one of the upper surface and the lower surface of the transparent member 1 may be beveled.

Alternatively, in the present embodiment, as a material of the transparent member 1, a borosilicate glass plate, for example, may be used, or in order to prevent moire caused by interference patterns in a certain direction, a low-pass filter formed of a quartz plate or a calcite plate which has birefringence properties may be used. Alternatively, as a material for the transparent member 1, a low-pass filter may be used which is formed of quartz plates or calcite plates attached on both sides of an infrared cut filter such that the birefringence properties are orthogonal to each other, or a transparent epoxy-based resin plate, a transparent acryl-based resin plate, or a transparent alumina plate may be used. Here, in the case of using the borosilicate glass plate as a material for the transparent member 1, the thickness of the transparent member 1 is set in the range from 200 μm to 1000 μm, and preferably in the range from 300 μm to 700 μm. The reason for setting the lower limit of the thickness of the transparent member 1 to 200 μm is that for mounting, the height of the semiconductor device including the transparent member 1, the transparent adhesive 12, the resin 4, the semiconductor element 2, the bonding pads 14, etc. is reduced to 500 μm or less, thereby obtaining a smaller and thinner semiconductor device. Moreover, the reason for setting the upper limit of the thickness of the transparent member 1 to 1000 μm is to obtain a transmittance of 90% or higher with respect to incident light having a wavelength of 500 μm. Furthermore, the reason for setting the preferable range of the thickness of the transparent member 1 in the range from 300 μm to 700 μm is to enable semiconductor devices to be fabricated most steadily by using an existing fabrication technology, and to obtain low-cost, small, thin semiconductor devices constituted of low-price, generalized products. It should be noted that in the case of using transparent alumina or a transparent resin as a material for the transparent member 1, the difference in transmittance of materials constituting the transparent member 1 is to be taken into consideration to determine the thickness of the transparent member 1. Alternatively, in the case of using quartz or calcite as a material for the transparent member 1, the distance between two images formed due to the birefringence relates to the thickness of the transparent member 1. Therefore, in addition to the difference in transmittance of the materials, the distance between the pixels in the light receiving region or the light emitting region of the semiconductor element 2 is to be taken into consideration to determine the thickness of the transparent member 1.

Moreover, in the present embodiment, the transparent adhesive 12 is an optically transparent adhesive used to attach the transparent member 1 on the light receiving region or the light emitting region of the semiconductor element 2. As a material for the transparent adhesive 12, an acryl-based resin, for example, may be used, or an epoxy-based resin or a polyimide-based resin in which the resin is mixed such that the absorption edge thereof does not fall within the wave range of visible light may be used. Moreover, the cured product property of the transparent adhesive 12 is that the transparent adhesive 12 has a refractive index lower than a refractive index of the microlens formed on the light receiving region or the light emitting region of the semiconductor element 2. This cured product property is given to the transparent adhesive 12 by at least one of ultraviolet irradiation and heating.

Moreover, in the present embodiment, the resin 4 is a light shielding resin. The light shielding resin is formed to cover part of the semiconductor element 2 except the light receiving region or the light emitting region in the upper surface of the semiconductor element 2 (that is, except a formation region for the transparent member 1) and to cover the side surfaces of the transparent member 1. The upper surface of the resin 4 is flat. The thickness of the resin 4 is approximately the same as the total thickness of the transparent member 1, the semiconductor element 2, and the substrate 3. Moreover, as a material for the resin 4, an epoxy-based resin may be used, or a low elasticity cured product such as a biphenyl-based resin or a silicone-based resin may be used, for example, to reduce the thickness of the base material of the semiconductor element 2, to improve thermal shock resistance and moisture resistance as a semiconductor device. For example, in the case where the resin 4 is molded by transfer molding using a molding die, a specific composition of the resin 4 includes an epoxy-based resin which is a half-cured powder resin in tablet form and serves as a main material, a hardening agent, a hardening accelerator, silica powder serving as inorganic filler, a fire retarding material, carbon black serving as a pigment, and a release agent. In particular, in the semiconductor device of the present embodiment, the selection and the amount of the inorganic filler and the pigment constituting the resin 4 are important for the warp and the light shielding property of the semiconductor device. Moreover, in order to lower the percentage of water absorption of the hardening agent for preventing a disconnection failure caused by the corrosion of wires of the semiconductor element 2, high purity silica which no longer has a crystalline quality due to melting processing is processed into balls having a variety of diameters to be properly mixed as a hardening agent. Moreover, the pigment is contained in the hardening agent of the resin 4 as much as possible but only to such an extent that insufficient insulation of the semiconductor device is not caused by reduction in electrical resistance in the hardening agent of the resin 4 in hot and humid surroundings. This blocks incident light around the transparent member 1 from entering the side surfaces of the transparent member 1 to become stray light. Specifically, as the pigment, carbon black having a hue exhibiting high light-shielding performance, for example, is used to stop a part of incident light from above the resin 4 from reaching a pn junction or a gate of a passive element or an active element on the upper surface (e.g., the principal plane) of the semiconductor element 2. This prevents erroneous operation of the semiconductor element 2. Here, as the pigment, it is important to select a material having a particle diameter and a low polarity which allow a high amount of the pigment to be contained in the hardening agent.

(Embodiment 2)

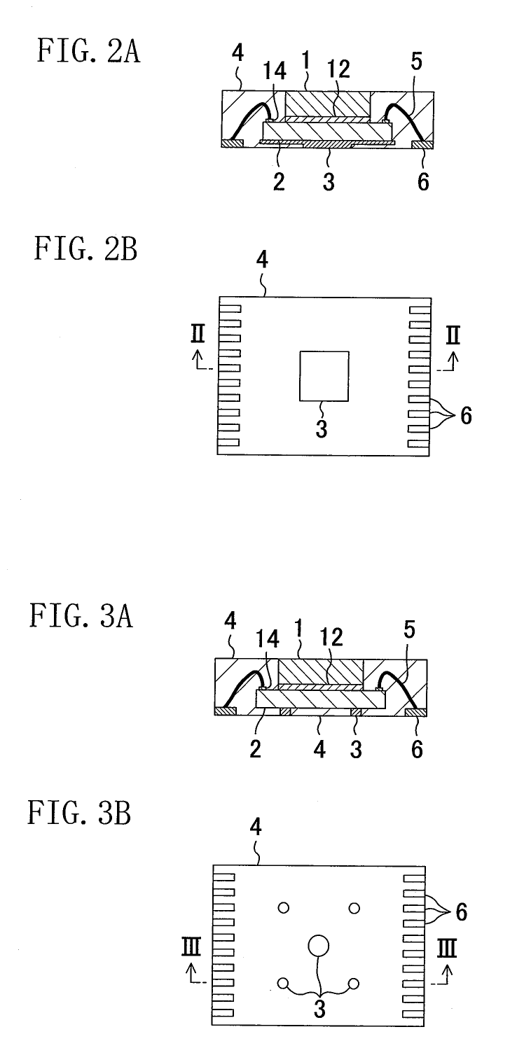

FIGS. 2A and 2B are a cross-sectional view and a plan view of a back surface (e.g., a die pad surface) of a semiconductor device according to Embodiment 2 of the present disclosure. It should be noted that FIG. 2A is a cross-sectional view along the line II-II of FIG. 2B. In FIGS. 2A and 2B, the same reference characters as those shown in Embodiment 1 of FIGS. 1A and 1B are used to represent equivalent components, and the same explanation thereof will be omitted.

As shown in FIGS. 2A and 2B, a semiconductor element 2 is die bonded to a substrate 3. On a light receiving region or a light emitting region of the semiconductor element 2 (on each of the light receiving region and the light emitting region when the semiconductor element has both of the regions), a transparent member 1 is attached with a transparent adhesive 12 interposed therebetween. The semiconductor element 2 has a plurality of bonding pads 14. The bonding pads 14 are electrically connected to respective ones of a plurality of connection terminals 6 assigned to the substrate 3 via respective ones of Au wires 5. The semiconductor element 2, the Au wires 5, and side surfaces of the transparent member 1 are covered with a resin 4. It should be noted that an upper surface of the transparent member 1 and part of a lower surface of the substrate 3 (including the connection terminals 6) are exposed from the resin 4.

The present embodiment is particularly configured such that an area corresponding to part of an upper surface of the semiconductor element 2, which part is covered with the resin 4 (i.e., a first area) is smaller than an area corresponding to parts of a lower surface of the semiconductor element 2 and the lower surface of the substrate 3, which parts are covered with the resin 4 (i.e., a second area). That is, in the present embodiment, the part of the lower surface of the semiconductor element 2 is covered with the resin 4 with a thinned portion of the substrate 3 interposed therebetween. It should be noted that the entirety of the lower surface of the substrate 3 to which the semiconductor element 2 is die bonded may be covered with the resin 4.

In the present embodiment, the area corresponding to the part of the upper surface of the semiconductor element 2 (that is, a formation surface for the light receiving region or the light emitting region), which part is covered with the resin 4 (i.e., the first area) is smaller than the area corresponding to the parts of the lower surface of the semiconductor element 2 and the lower surface of the substrate 3, which parts are covered with the resin 4 (i.e., the second area). In other words, the resin 4 is sufficiently filled into the space under the lower surface of the semiconductor element 2 opposite to the transparent member 1. This can suppress the formation of contraction stress of the resin 4 at its portion close to the transparent member 1. Thus, it is possible to reduce a concave warp of the semiconductor device, particularly a concave warp of the transparent member 1 caused by the contraction stress. Moreover, the resin 4 is also filled into the space under the lower surface of the substrate 3 on which the semiconductor element 2 is provided. This can further suppress the formation of the contraction stress of the resin 4 at its portion close to the transparent member 1. Thus, it is possible to further reduce the concave warp of the transparent member 1. Therefore, in the case where the transparent member 1 is directly attached to a lens module such as a prism, the entire surface of the transparent member 1 can be adhered easily to the lens module. This can prevent an inclination from being caused at an adhesive section between the transparent member 1 and the lens module, thereby preventing their optical axes from being shifted, and can prevent the lens module such as a prism from being damaged. As a result, the time required for the assembly operation can be shortened, and the quality can be prevented from being lowered. Consequently, it is possible to provide a low-cost, highly reliable semiconductor device with the problems in optical properties being prevented.

In the present embodiment, the plurality of bonding pads 14 of the semiconductor element 2 is electrically connected to the respective ones of the plurality of connection terminals 6 assigned to the substrate 3 via the respective ones of the Au wires 5. However, bonding wires made of another material may be used instead of the Au wires 5. Moreover, the semiconductor element 2 may be connected to the substrate 3 by flip-chip bonding instead of wire bonding.

Moreover, in the present embodiment, the area corresponding to the parts of the lower surface of the semiconductor element 2 and the lower surface of the substrate 3, which parts are covered with the resin 4 (i.e., the second area) is preferably at least 1.5 or more times as large as the area corresponding to the part of the upper surface of the semiconductor element 2, which part is covered with the resin 4 (i.e., the first area). More preferably, the second area is two or more times as large as the first area. This structure ensures the advantages of the aforementioned present embodiment.

(Embodiment 3)

FIGS. 3A and 3B are a cross-sectional view and a plan view of a back surface (e.g., a die pad surface) of a semiconductor device according to Embodiment 3 of the present disclosure. It should be noted that FIG. 3A is a cross-sectional view along the line of FIG. 3B. In FIGS. 3A and 3B, the same reference characters as those shown in Embodiment 1 of FIGS. 1A and 1B are used to represent equivalent components, and the same explanation thereof will be omitted.

As shown in FIGS. 3A and 3B, a semiconductor element 2 is die bonded to a substrate 3. On a light receiving region or a light emitting region of the semiconductor element 2 (on each of the light receiving region and the light emitting region when the semiconductor element has both of the regions), a transparent member 1 is attached with a transparent adhesive 12 interposed therebetween. The semiconductor element 2 has a plurality of bonding pads 14. The bonding pads 14 are electrically connected to respective ones of a plurality of connection terminals 6 assigned to the substrate 3 via respective ones of Au wires 5. The semiconductor element 2, the Au wires 5, and side surfaces of the transparent member 1 are covered with a resin 4. It should be noted that an upper surface of the transparent member 1 and part of a lower surface of the substrate 3 (including the connection terminals 6) are exposed from the resin 4.

The present embodiment is particularly configured such that lower surfaces of a plurality of parts apart from each other of the substrate 3 (including the connection terminals 6) are exposed from the resin 4. In other words, the space under a lower surface of the semiconductor element 2 except the exposed surfaces of the substrate 3 is filled with the resin 4. Similar to Embodiment 1, the area of the lower surfaces (exposed surfaces) of the substrate 3 may be smaller than the area of the upper surface of the transparent member 1. Moreover, as in Embodiment 2, an area corresponding to a part of an upper surface of the semiconductor element 2, which part is covered with the resin 4 (i.e., a first area) may be smaller than an area corresponding to part of the lower surface of the semiconductor element 2, which part is covered with the resin 4 (i.e., a second area). Here, if part of the lower surface of the semiconductor element 2 is covered with the resin 4 with a thinned portion of the substrate 3 interposed therebetween, the area of the lower surface of the thinned portion of the substrate 3 is also included in the “second area”. Moreover, the “second area” is preferably 1.5 or more times as large as the “first area,” and more preferably two or more times as large as the “first area.” It should be noted that the entirety of the lower surface of the substrate 3 may be covered with the resin 4.

The present embodiment can provide the below-described advantage in addition to advantages similar to those of Embodiment 1 or Embodiment 2. That is, since the resin 4 is sufficiently filled into the space under the lower surface of the semiconductor element 2, it is possible to further suppress the formation of contraction stress of the resin 4 at its portion close to the transparent member 1. This can further reduce a concave warp of the transparent member 1.

In the present embodiment, the plurality of bonding pads 14 of the semiconductor element 2 is electrically connected to the respective ones of the plurality of connection terminals 6 assigned to the substrate 3 via the respective ones of the Au wires 5. However, bonding wires made of another material may be used instead of the Au wires 5. Moreover, the semiconductor element 2 may be connected to the substrate 3 by flip-chip bonding instead of wire bonding.

(Embodiment 4)

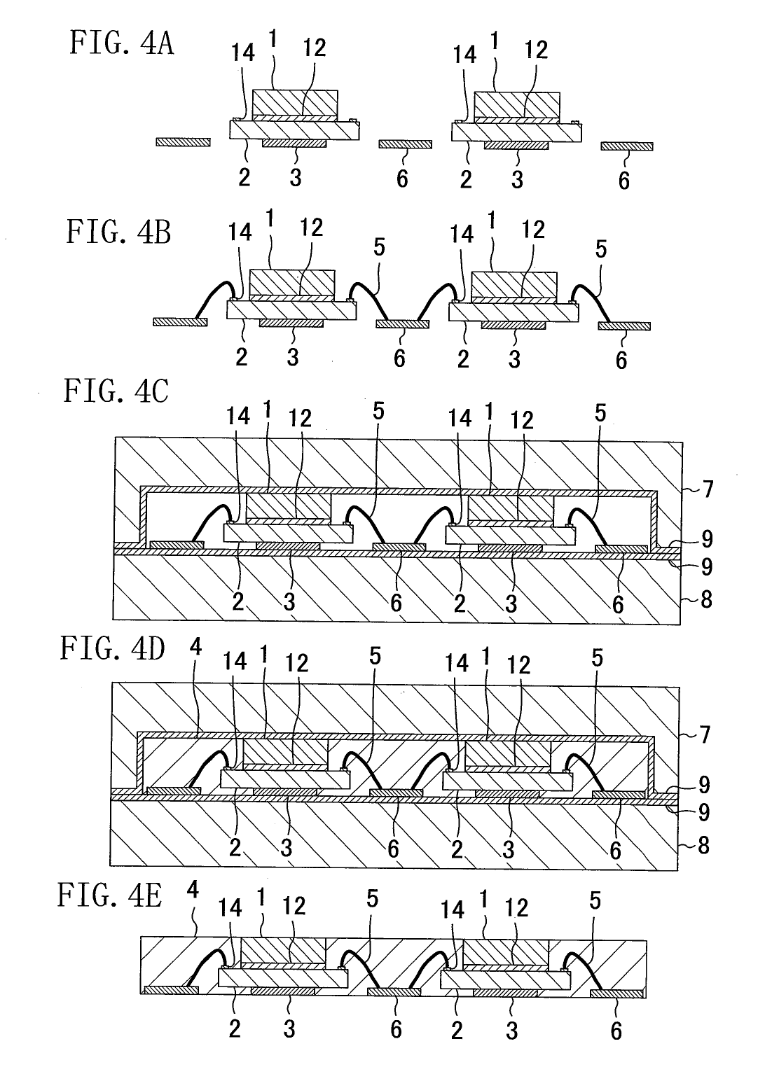

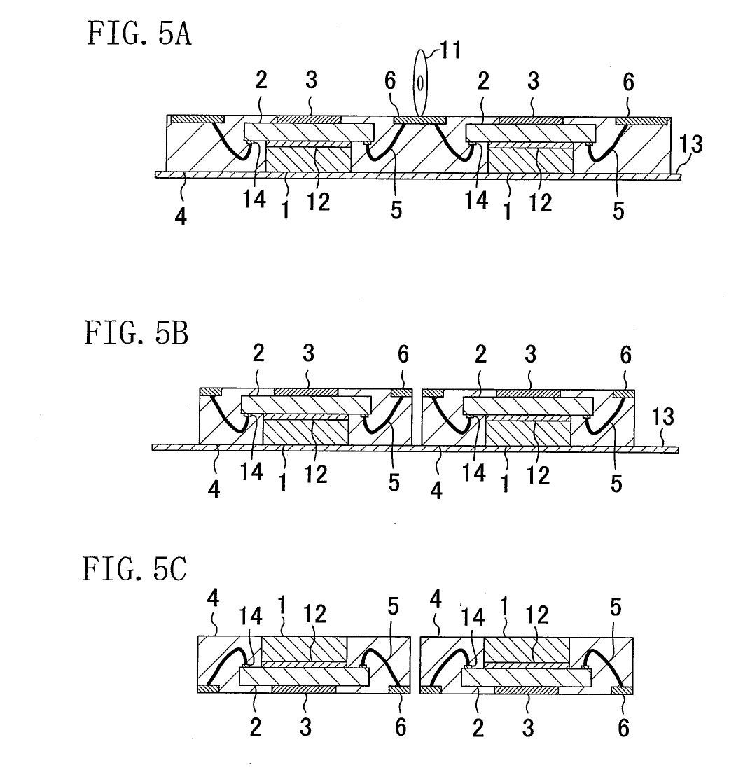

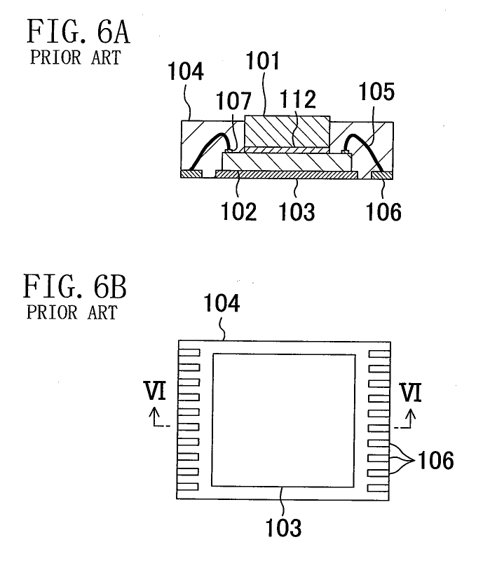

FIGS. 4A through 4E and FIGS. 5A through 5C are cross-sectional views illustrating processes in a method for fabricating a semiconductor device according to Embodiment 4 of the present disclosure. In the present embodiment, a method for fabricating the semiconductor device according to Embodiment 1 of FIGS. 1A and 1B will be described as an example. However, the semiconductor device according to Embodiment 2 of FIGS. 2A and 2B and the semiconductor device according to Embodiment 3 of FIGS. 3A and 3B can be fabricated using a method similar to the method of the present embodiment described below. In FIGS. 4A through 4E and FIGS. 5A through 5C, the same reference characters as shown in Embodiment 1 of FIGS. 1A and 1B are used to represent equivalent components, and the same explanation thereof will be omitted.

First, as illustrated in FIG. 4A, a plurality of semiconductor elements 2 is die bonded to a substrate 3, wherein on a light receiving region or a light emitting region of each semiconductor element 2 (on the light receiving region and the light emitting region when the semiconductor element has both of the regions), a transparent member 1 is attached with a transparent adhesive 12 interposed therebetween, and each semiconductor element 2 has a plurality of bonding pads 14. The semiconductor elements 2 are arranged in a two-dimensional matrix pattern spaced apart at a predetermined distance from one another.

Next, as illustrated in FIG. 4B, the bonding pads 14 on each semiconductor element 2 are electrically connected to respective ones of a plurality of connection terminals 6 assigned to the substrate 3 by respective ones of the Au wires 5.

Next, as illustrated in FIG. 4C, the substrate 3 having the plurality of semiconductor elements 2 die bonded thereon is clamped, with release sheets 9 being provided respectively between a surface of an upper die 7 and upper surfaces of the transparent members 1 and between a surface of a lower die 8 and a lower surface of the substrate 3. Subsequently, as illustrated in FIG. 4D, the resin 4 sealing the semiconductor elements 2, the Au wires 5, and side surfaces of the transparent members 1 is molded, with the upper surfaces (e.g., the principal planes) of the transparent members 1 being covered with the release sheet 9. Here, the space between the semiconductor elements 2 is filled with the resin 4, wherein the semiconductor elements 2 are arranged in the two-dimensional matrix pattern on the substrate 3, and the transparent members 1 are respectively attached on the semiconductor elements 2.

Next, as illustrated in FIG. 4E, the upper die 7 and the lower die 8 are removed from the resin-sealed substrate 3. Then, as illustrated in FIG. 5A, the resin-sealed substrate 3 is adhered to a dicing sheet 13. In FIG. 5A, a transparent member 1 side is adhered to the dicing sheet 13. However, a substrate 3 side (die pad side) may be adhered to the dicing sheet. Subsequently, the substrate 3 having the plurality of semiconductor element 2 arranged in the two-dimensional matrix pattern thereon is diced using a dicing blade 11. In this way, as illustrated in FIG. 5B, the substrate 3 is cut to separate the semiconductor elements 2 from one another, thereby a plurality of semiconductor devices can be formed in one process.

Finally, as illustrated in FIG. 5C, the semiconductor devices are detached from the dicing sheet 13 for cleaning.

According to the present embodiment, after resin sealing, the substrate 3 is diced for each semiconductor element 2, thereby a plurality of semiconductor devices can be formed in one process. Moreover, the resin sealing is carried out while the substrate 3 is clamped, with the release sheets 9 being provided respectively between the surface of the upper die 7 and the upper surfaces of the transparent members 1 and between the surface of the lower die 8 and the lower surface of the substrate 3. Thus, the resin 4 does not come into contact with the upper surfaces of the transparent members 1 and the lower surface of the substrate 3 which are respectively covered with the release sheets 9. Therefore, it is possible to obtain semiconductor devices in which the resin 4 does not cover the upper surfaces of the transparent members 1 and the lower surface of the substrate 3.

Note that in the present embodiment, a material for the release sheets 9 may be, but is not particularly limited to, for example, a resin containing fluorine. Moreover, in the present embodiment, in the process illustrated with reference to

FIG. 4C, instead of providing the release sheet 9 between the surface of the lower die 8 and the lower surface of the substrate 3, a heat-resistant sheet may be adhered to the lower surface of the substrate 3 (that is, an opposite surface of the surface of the substrate 3 on which the semiconductor elements 2 are die bonded). In this way, the release sheet 9 for the lower surface (exposed surface) of the substrate 3 on which the semiconductor elements 2 are die bonded can be dispensed with. Thus, clamping using the dies 7 and 8 for resin sealing can be performed more stably. Therefore, it is possible to further increase yield of the semiconductor device. Here, a material for the heat-resistant sheet may be, but is not particularly limited to, for example, a resin containing fluorine.

Moreover, in the present embodiment, the kind of the dicing sheet 13 is not particularly limited to a specific one. For example, a sheet may be used which includes polyvinyl chloride, polyolefin, polyethylene terephthalate (PET), or the like as a base material, and an acryl-based or epoxy-based adhesive.

What is claimed is:

1. A semiconductor device comprising:
a semiconductor element having
a light receiving region or a light emitting region on which a transparent member is attached and
a plurality of electrode pads;
a substrate on which the semiconductor element is provided; and
a resin covering the semiconductor element and side surfaces of the transparent member, wherein
an area of a lower surface of the substrate is smaller than an area of an upper surface of the transparent member.

2. The semiconductor device comprising:
a semiconductor element having
a light receiving region or a light emitting region on which a transparent member is attached and
a plurality of electrode pads;
a substrate on which the semiconductor element is provided; and
a resin covering the semiconductor element and side surfaces of the transparent member, wherein
a first area corresponding to part of an upper surface of the semiconductor element, which part is covered with the resin is smaller than a second area corresponding to parts of a lower surface of the semiconductor element and a lower surface of the substrate, which parts are covered with the resin.

3. The semiconductor device of claim 2, wherein a thickness of part of the substrate in which the lower surface of the substrate is covered with the resin is smaller than a thickness of the other part of the substrate.

4. The semiconductor device of claim 2, wherein the second area is 1.5 or more times as large as the first area.

5. The semiconductor device of claim 2, wherein at least part of the lower surface of the substrate is exposed from the resin.

6. The semiconductor device of claim 2, wherein lower surfaces of a plurality of parts of the substrate which are apart from each other are exposed form the resin.

7. The semiconductor device of claim 2, further comprising:
a plurality of connection terminals assigned to the substrate; and
bonding wires electrically connecting the plurality of electrode pads to corresponding ones of the plurality of connection terminals.

8. The semiconductor device of claim 7, wherein the bonding wires are made of gold.

9. The semiconductor device of claim 2, wherein the semiconductor element is flip-chip bonded to the substrate.

10. The semiconductor device of claim 2, wherein the transparent member is attached on the light receiving region or the light emitting region of the semiconductor element with a transparent adhesive interposed therebetween.

11. A method for fabricating the semiconductor device of claim 2, the method comprising:
preparing the substrate on which multiple ones of the semiconductor element are arranged in a matrix pattern;
molding the resin while the substrate is clamped, with release sheets being provided respectively between a die surface and upper surfaces of the transparent members and between a die surface and the lower surface of the substrate; and
after the molding, cutting the substrate to separate the semiconductor elements from one another.

12. The method of claim 11, wherein in the molding, a heat-resistant sheet is provided instead of the release sheet between the die surface and the lower surface of the substrate.
